(19) United States
(12) Patent Application Publication
(10) Pub. No.: US 2014/0069331 A1
(43) Pub. Date: Mar. 13, 2014

(54) MASK AND MANUFACTURING METHOD THEREOF

(71) Applicant: Tai-Pi Wu, Guangdong (CN)

(72) Inventor: Tai-Pi Wu, Guangdong (CN)

(73) Assignee: SHENZEN CHINA STAR OPTOELECTRONICS TECHNOLOGY CO., LTD., Guangdong (CN)

(21) Appl. No.: 13/702,052

(22) PCT Filed: Sep. 20, 2012
(86) PCT No.: PCT/CN2012/081646

§ 371 Date: Dec. 4, 2012

(30) Foreign Application Priority Data
Sep. 12, 2012 (CN) 201210336373.7

(51) Int. Cl. C23C 16/04

(52) U.S. Cl. CPC C23C 16/042
USPC 118/500; 29/428

(57) ABSTRACT

A mask disclosed in the present invention includes: a first sub-mask and one side edge thereof includes a first structure; a second sub-mask and one side edge thereof includes a second structure; the first sub-mask and the second sub-mask are disposed in parallel and arranged together, and the first sub-mask and the second sub-mask are on the same plane, and the first structure and the second structure are structures complementary to each other. The present invention also discloses a mask manufacturing method. The present invention can achieve a large size mask.

### FIELD OF THE INVENTION

The present invention relates to a field of mask, and more particularly to a mask and a manufacturing method thereof.

### BACKGROUND OF THE INVENTION

Currently, according to the technological development, the society is paying more and more attention toward an Organic Light Emitting Diode (OLED). A large size OLED display panel is an unstoppable trend in the technological development.

The display principle of the OLED display panel is different from the display principle of the liquid crystal display (LCD) panel, and accordingly the manufacturing methods are different. The OLED display panel includes an organic material layer. In the manufacturing process of the OLED display panel, the organic material layer is made by a vapor depositing technique and the vapor depositing technique is required to use a mask.

The mask is a significant component in a vapor depositing technique. Currently, the size of the mask used in the vapor depositing technique is limited, and it would restrict the large size development of the OLED display panel. In addition, the limited size of the mask will cause the organic material layer to deposit on other areas of a Thin Film Transistor (TFT) array in the vapor depositing process, and thereby affect the quality of the OLED display panel.

Therefore, it is necessary to provide a novel technique method to solve the problems described above.

### SUMMARY OF THE INVENTION

An object of the present invention is to provide a mask in the present invention to achieve a large size mask so as to implement in the large size organic light emitting diode (OLED) display panel.

For achieving the above-mentioned resolution, the present invention proposes a mask which comprises: a first sub-mask and one side edge thereof includes a first structure; a second sub-mask and one side edge thereof includes a second structure; the first sub-mask and the second sub-mask are disposed in parallel and arranged together, the first sub-mask and the second sub-mask are on the same plane, and the first structure and the second structure are structures complementary to each other; the first sub-mask includes a first surface and a second surface, and the first surface the second surface are opposite to each other, the second sub-mask includes a third surface and a fourth surface and the third surface and the fourth surface are opposite to each other, the first sub-mask and the second sub-mask are disposed in parallel and arranged together, and the first surface of the first sub-mask and the third surface of the second sub-mask are on the same plane, and the second surface of the first sub-mask and the fourth surface of the second sub-mask are on the same plane; the first structure and the second structure are formed by etching or cutting the first sub-mask and the second sub-mask, and the first structure of the first sub-mask and the second structure of the second sub-mask are stacked together.

As the mask described above, the first structure and the second structure are structures complementary to each other in a first direction and the first direction is perpendicular to a direction of the first surface, and the first structure of the first sub-mask and the second structure of the second sub-mask are stacked together in the first direction.

As the mask described above, the first structure is a latch and the second structure is a latch groove.

As the mask described above, the first structure and the second structure are structures complementary to each other in a second direction, and the second direction and a direction of a straight line connected from a center of the first sub-mask to a center of the second sub-mask are in parallel, and the first structure of the first sub-mask and the second structure of the second sub-mask are stacked together in the second direction.

As the mask described above, the first structure is a sawtooth protrusion with a latch and the second structure is a sawtooth depression with a latch concave.

Another object of the present invention is to provide a mask to achieve the large size mask to implement in the large size OLED display panel.

For achieving the above-mentioned resolution, the present invention proposes a mask which comprises: a first sub-mask and one side edge thereof includes a first structure; a second sub-mask and one side edge thereof includes a second structure; the first sub-mask and the second sub-mask are disposed in parallel and arranged together, and the first sub-mask and the second sub-mask are on the same plane, and the first structure and the second structure are structures complementary to each other.

As the mask described above, the first sub-mask includes a first surface and a second surface, and the first surface and the second surface are opposite to each other, the second sub-mask includes a third surface and a fourth surface and the third surface and the fourth surface are opposite to each other, the first sub-mask and the second sub-mask are disposed in parallel and arranged together, and the first surface of the first sub-mask and the third surface of the second sub-mask are on the same plane, and the second surface of the first sub-mask and the fourth surface of the second sub-mask are on the same plane.

As the mask described above, the first structure and the second structure are structures complementary to each other in a first direction, the first direction is perpendicular to a direction of the first surface, and the first structure of the first sub-mask and the second structure of the second sub-mask are stacked together in the first direction.

As the mask described above, the first structure is a latch and the second structure is a latch groove.

As the mask described above, the first structure and the second structure are structures complementary to each other in a second direction, and the second direction and a direction of a straight line connected from a center of the first sub-mask to a center of the second sub-mask are in parallel, and the first structure of the first sub-mask and the second structure of the second sub-mask are stacked together in the second direction.

As the mask described above, the first structure is a sawtooth protrusion with latch and the second structure is a sawtooth depression with latch concave.

Another object of the present invention is to provide a mask manufacturing method to achieve the large size mask to implement in the large size OLED display panel.

For achieving the above-mentioned object, the present invention proposes a mask manufacturing method, comprising: (A) providing a first sub-mask and a second sub-mask, and one side edge of the first sub-mask includes a first structure and one side edge of the second sub-mask includes a second structure and the first structure and the second structure are structures complementary to each other; (B) connecting the first sub-mask and the second sub-mask together to make the first sub-mask and the second sub-mask on the same plane and the first structure of the first sub-mask and the second structure of the second sub-mask are stacked together.

As the mask manufacturing method described above, the step (A) further comprises the following steps: (a1) defining size and place of the first structure and the second structure to make the first structure and the second structure be structures complementary to each other; (a2) forming the first structure on the first sub-mask and the second structure on the second sub-mask.

As the mask manufacturing method described above, the first structure of the first sub-mask and the second structure of the second sub-mask are stacked together in the first direction, the first direction is perpendicular to a direction of the first surface and the first structure is a latch and the second structure is a latch groove.

As the mask manufacturing method described, the first structure of the first sub-mask and the second structure of the second sub-mask are stacked together in the second direction, the second direction is parallel to a direction of a straight line connected from a center of the first sub-mask to a center of the second sub-mask, and the first structure is a sawtooth protrusion with latch and the second structure is a sawtooth depression with latch concave.

The above-mentioned description of the present invention can be best understood by referring to the following detailed description of the preferred embodiments and the accompanying drawings.

### DESCRIPTION OF THE DRAWINGS

FIG. 1 is an isometric drawing illustrating a mask in a first preferred embodiment of the present invention;

FIG. 2 is an A-A′ sectional view in FIG. 1;

FIG. 3 is a view illustrating a second preferred embodiment of the present invention;

FIG. 4 is a view illustrating a third preferred embodiment of the present invention;

FIG. 5 is a view illustrating a fourth preferred embodiment of the present invention;

FIG. 6 is a flowchart illustrating a mask manufacturing method in the present invention.

### DETAILED DESCRIPTION OF THE PREFERRED EMBODIMENTS

In the following detailed description of the preferred embodiments, reference is made to the accompanying drawings which form a part hereof, and as shown by way of illustration specific embodiments in which the invention may be practiced. As such, the directional terminology is used for purposes of illustration and is in no way limiting the present invention.

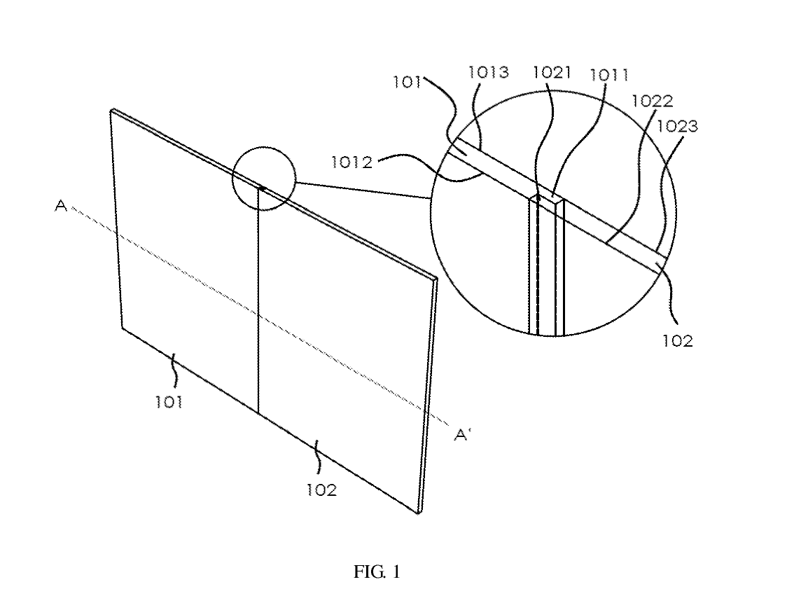

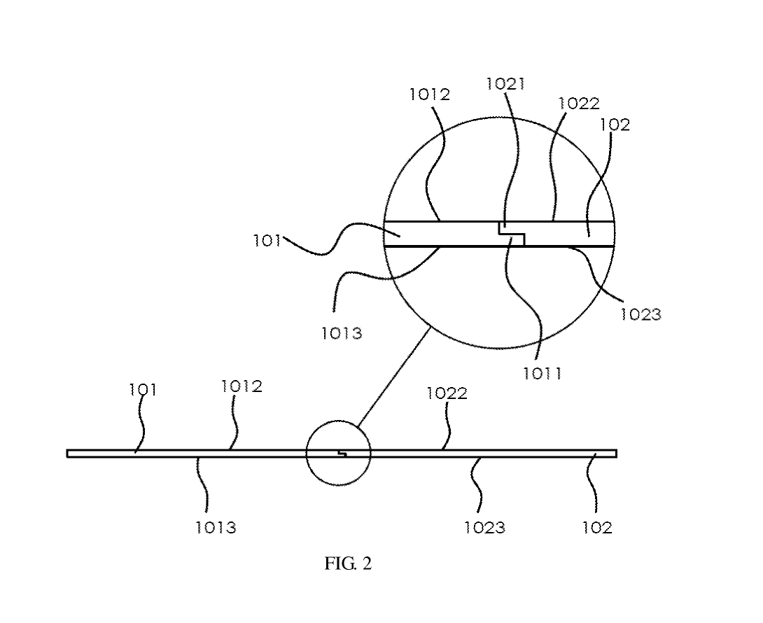

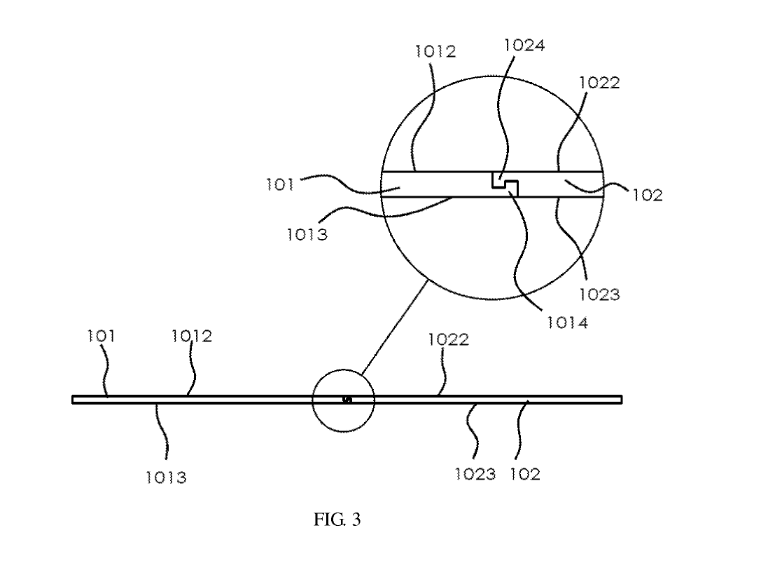

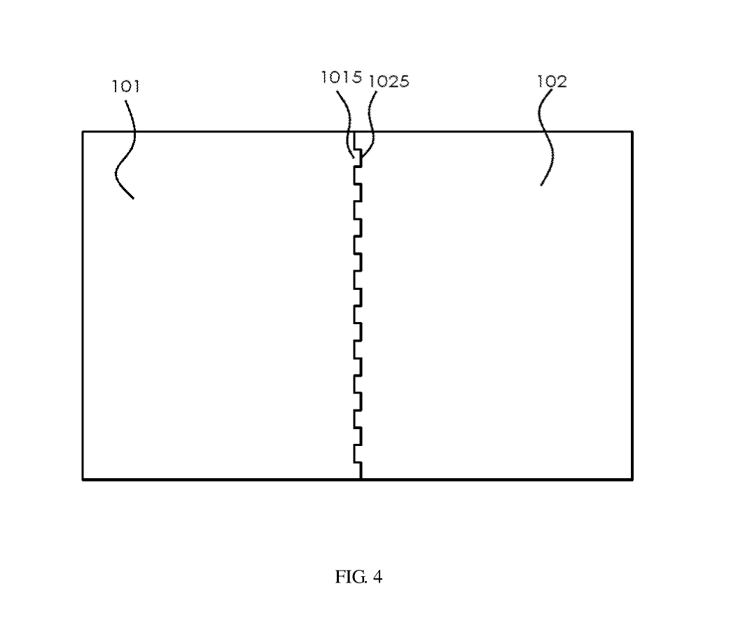

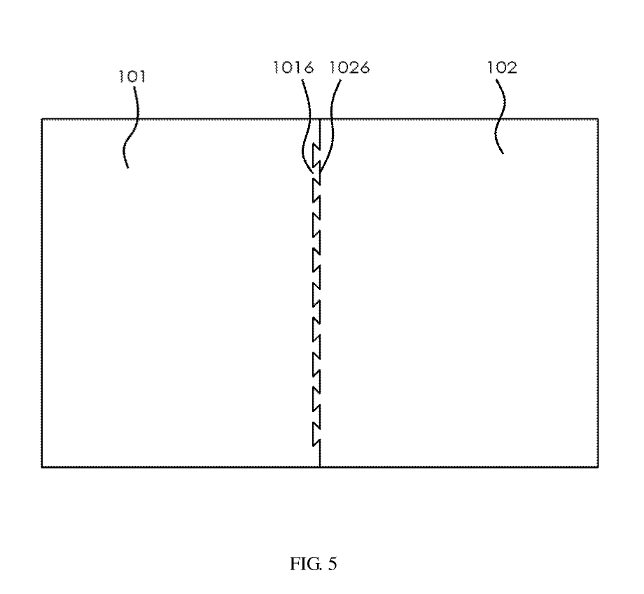

Please refer to FIG. 1, FIG. 2, FIG. 3, FIG. 4, and FIG. 5 in conjunction, FIG. 1 is an isometric drawing illustrating a mask in a first preferred embodiment of the present invention. FIG. 2 is an A-A′ sectional view in FIG. 1. FIG. 3, FIG. 4 and FIG. 5 are views illustrating respectively a second, a third and a fourth preferred embodiment of the present invention. The mask in the present invention includes at least two sub-masks, and practically includes a first sub-mask 101 and a second sub-mask 102. One side edge of the first sub-mask 101 includes a first structure (such as a first platform 1011 in FIG. 1 and FIG. 2, a latch 1014 in FIG. 3, a sawtooth protrusion 1015 in FIG. 4 and a sawtooth protrusion with latch 1016 in FIG. 5). One side edge of the second sub-mask 102 includes a second structure (such as a second platform 1021 in FIG. 1 and FIG. 2, a latch groove 1024 in FIG. 3, a sawtooth depression 1025 in FIG. 4 and a sawtooth depression with latch concave 1026). The first structure and the second structure are structures complementary to each other. The places in the first structure are flat and the corresponding places in the second structure are also flat. The places in the first structure are protruded and the corresponding places in the second structure are concaved and vice versa. Therefore, the first structure and the second structure can be coupled together.

In the mask of the present invention, the first sub-mask 101 and the second sub-mask 102 are disposed in parallel and arranged together, and the first sub-mask 101 and the second sub-mask 102 are on the same plane. The first structure and the second structure are stacked together. In the mask of the present invention, both of the first structure and the second structure can be disposed at two side edges of the first sub-mask 101 and the second sub-mask 102. In a different embodiment, the first structures can be disposed in two side edges of the first sub-mask 101 and the second structures in two side edges of the second sub-mask 102. Therefore, more sub-masks can be connected together to satisfy the requirement for the large size mask.

The first sub-mask 101 includes a first surface 1012 and a second surface 1013, and the first surface 1012 and the second surface 1013 are opposite to each other. The second sub-mask 102 includes a third surface 1022 and a fourth surface 1023, and the third surface 1022 and the fourth surface 1023 are opposite to each other. The first sub-mask 101 and the second sub-mask 102 are disposed in parallel and arranged together. The first surface 1012 of the first sub-mask 101 and the third surface 1022 of the second sub-mask 102 are on the same plane. The second surface 1013 of the first sub-mask 101 and the fourth surface 1023 of the second sub-mask 102 are on the same plane.

As shown in FIG. 1, FIG. 2 and FIG. 3, the first structure and the second structure are structures complementary to each other in a first direction. The first direction is perpendicular to the direction of the first surface 1012. The first structure of the first sub-mask 101 and the second structure of the second sub-mask 102 are stacked together in the first direction. Practically, in FIG. 1 and FIG. 2, the first structure in the first sub-mask 101 is a first platform 1011, and the bottom surface of the first platform 1011 is in the same surface as the second surface 1013 (disposed on the same plane). The thickness of the first platform 1011 in the first direction is smaller than the thinness of the first sub-mask 101 in the first direction. The second structure in the second sub-mask 102 is the second platform 1021, and the bottom surface of the second platform 1021 and the third surface 1022 are on the same plane. The thickness of the second platform 1021 in the first direction is smaller than the thickness of the second sub-mask 102 in the first direction. The summation of the thickness of the first platform 1011 in the first direction and the thickness of the second platform 1021 in the first direction is equal to or approximately equal to the thickness of the first sub-mask 101 or the second sub-mask 102 in the first direction. In other words, the first structure as the first platform 1011 and the second structure as the second platform 1021 are structures complementary to each other in the first direction. The first direction is perpendicular to the direction of the first surface of the first sub-mask 101. As a modification of the first structure and the second structure in FIG. 2, in FIG. 3, the first structure of the first sub-mask 101 is a latch 1014, and the second structure of the second sub-mask 102 is a latch groove 1024 (or another latch with the reverse direction as the latch 1014). The latch 1014 and the latch groove 1024 are structures complementary to each other in the first direction. The latch 1014 and the latch groove 1024 are configured to connect the first sub-mask 101 and the second sub-mask 102 together and the first sub-mask 101 and the second sub-mask 102 are latched to each other. Therefore, the first sub-mask 101 and the second sub-mask 102 are strictly connected together to avoid the separation when the first sub-mask 101 and the second sub-mask 102 are assembled together to be a mask. The OLED display panel would be damaged during the manufacturing process because the mask is loosed.

As shown in FIG. 4 and FIG. 5, FIG. 4 and FIG. 5 are top views illustrating the mask in the present invention. The first structure and the second structure are structures complementary to each other in the second direction. The second direction is parallel to the direction of the straight line connected from the center of the first sub-mask 101 to the center of the second sub-mask 102. The first structure of the first sub-mask 101 and the second structure of the second sub-mask 102 are stacked together in the second direction. Practically, in FIG. 4, the first structure of the first sub-mask 101 is a sawtooth protrusion 1015 and the sawtooth protrusion 1015 is extended from the side surface of the first sub-mask 101 to the vertical direction of the side surface. The second structure of the sub-mask 102 is a sawtooth depression 1025, and the sawtooth depression 1025 is depressed from the side surface of the second sub-mask 102 to the vertical direction of the second sub-mask 102. The size, dimension or position of the sawtooth depression 1025 is corresponding to the size, dimension or position of the sawtooth protrusion 1015. In other words, the first structure shown as the sawtooth protrusion 1015 and the second structure shown as the sawtooth depression 1025 are structures complementary to each other. As a modification of the first structure and the second structure in FIG. 4, in FIG. 5, the first structure of the first sub-mask 101 is a sawtooth protrusion with latch 1016 and the second structure of the second sub-mask 102 is a sawtooth depression with latch concave 1026. The sawtooth protrusion with latch 1016 ad the sawtooth depression with latch concave 1026 are structures complementary to each other in the second direction. The sawtooth protrusion with latch 1016 and the sawtooth depression with latch concave 1026 are configured to connect the first sub-mask 101 and the second sub-mask 102 together and the first sub-mask 101 and the second sub-mask 102 are latched together. Therefore, the first sub-mask 101 and the second sub-mask 102 are strictly connected to avoid the separation when the first sub-mask 101 and the second sub-mask 102 are assembled together to be a mask. The OLED display panel would be damaged during the manufacturing process because the mask is loosed.

The first structure and the second structure described above can be formed by etching or cutting the first sub-mask 101 and the second sub-mask 102. Before etching or cutting the first sub-mask 101 and the second sub-mask 102 to form the first structure and the second structure, the size or position of first structure and the second structure needs to be defined or designed to make sure that the first structure and the second structure are structures complementary to each other.

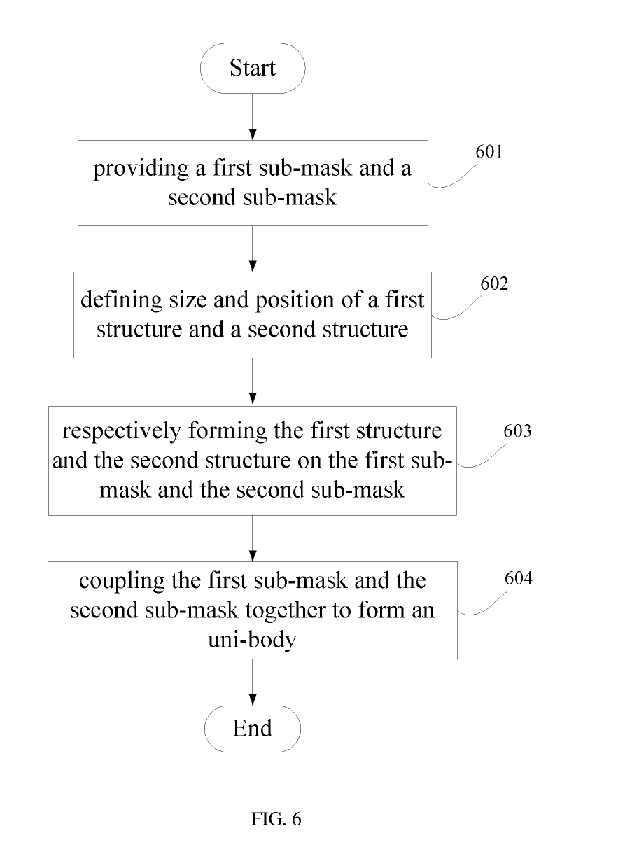

Please refer to FIG. 6, FIG. 6 is a flowchart illustrating the manufacturing method of the mask in the present invention. The mask in the present invention includes at least two sub-masks and the at least two sub-masks are disposed in parallel and arranged together. The two adjacent sub-masks are connected to each other to form the mask in the present invention.

In step 601, it is to provide at least two sub-masks. Practically, a first sub-mask 101 and a second sub-mask 102 are provided. One side edge of the first sub-mask 101 includes a first structure and one side edge of the second sub-mask 102 includes a second structure. The first structure and the second structure are structures complementary to each other. In other words, if the places in the first structure are flat, the places in the second structure are also flat. If the place in the first structure is protruded, the place in the second structure is concaved and vice versa. Therefore, the first structure and the second structure can be latched to each other. In the method described above, the first structure and the second structure can be disposed at two side edge of the first sub-mask 101 and the second sub-mask 102. Or, the first structure is disposed in two side edges of the first sub-mask 101 and the second structure is disposed in two side edges of the second sub-mask 102. Therefore, more sub-masks can be connected together to satisfy the requirement for the large size mask.

In step 602, it is to define the size and place of the first structure and the second structure to make sure the first structure and the second structure are structures complementary to each other. For example, as shown in FIG. 1 and FIG. 2, the first structure and the second structure are two platforms (the first platform 1011 and the second platform 1021) with different bottom surface and different extending direction. As shown in FIG. 3, the first structure is a latch 1014 and the second structure is a latch groove 1024 (or another latch with the reversed direction as the latch 1014). As shown in FIG. 4, the first structure is a sawtooth protrusion 1015 and the second structure is a sawtooth depression 1025. As shown in FIG. 5, the first structure is a sawtooth protrusion with latch 1016, and the second structure is a sawtooth depression with latch concave 1026.

In step 603, it is to etch or cut the first sub-mask 101 to form the first structure and also etch or cut the second sub-mask 102 to form the second structure.

In step 604, it is to connect the first sub-mask 101 and the second sub-mask 102 together as a unibody and the first structure of the first sub-mask 101 and the second structure of the second sub-mask 102 are stacked together. Practically, the first structure of the first sub-mask 101 and the second structure of the second sub-mask 102 are stacked together in the first direction. The first direction is perpendicular to the direction of the first surface 1012. And/or the first structure of the first sub-mask 101 and the second structure of the second sub-mask 102 are stacked together in the second direction. The second direction is parallel to the straight line connected from the center of the first sub-mask 101 to the center of the second sub-mask 102. The first surface 1012 of the first sub-mask 101 and the third surface 1022 of the second sub-mask 102 are on the same plane. The second surface 1013 of the first sub-mask 101 and the fourth surface 1023 of the second sub-mask 102 are on the same plane.

In the present invention, by connecting the at least two sub-masks together, the large size mask can be achieved. The organic material evaporated to deposit on the other areas of the TFT array platform to affect the product quality of the organic OLED display panel during the manufacturing process of the OLED display panel in the present invention can be avoided so as to provide a good condition to enlarge the size of the OLED display panel. In addition, the mask in the present invention can be modified in accordance with the practical situation in the OLED display panel manufacturing process to satisfy the requirement of the manufacturing process for different size OLED display panel.

As described above, the present invention has been described with preferred embodiments thereof and it is understood that many changes and modifications to the described embodiments can be carried out without departing from the scope and the spirit of the invention that is intended to be limited only by the appended claims.

What is claimed is:

1. A mask, comprising:
a first sub-mask comprising a first structure at one side edge thereof;
a second sub-mask comprising a second structure at one side edge thereof;
the first sub-mask and the second sub-mask being disposed in parallel and arranged together, and the first sub-mask and the second sub-mask are on a same plane, and the first structure and the second structure are structures complementary to each other;
the first sub-mask having a first surface and a second surface, and the first surface and the second surface being opposite to each other, the second sub-mask having a third surface and a fourth surface, and the third surface and the fourth surface being opposite to each other, the first sub-mask and the second sub-mask being disposed in parallel and arranged together, the first surface of the first sub-mask and the third surface of the second sub-mask are on the same plane, and the second surface of the first sub-mask and the fourth surface of the second sub-mask are on the same plane;
the first structure and the second structure being formed by etching or cutting the first sub-mask and the second sub-mask, and the first structure of the first sub-mask and the second structure of the second sub-mask being stacked together.

2. The mask according to claim 1, wherein the first structure and the second structure are structures complementary to each other in a first direction and the first direction is perpendicular to a direction of the first surface, and the first structure of the first sub-mask and the second structure of the second sub-mask are stacked together in the first direction.

3. The mask according to claim 2, wherein the first structure is a latch and the second structure is a latch groove.

4. The mask according to claim 1, wherein the first structure and the second structure are structures complementary to each other in a second direction, and the second direction is parallel to a direction of a straight line connected from a center of the first sub-mask to a center of the second sub-mask, and the first structure of the first sub-mask and the second structure of the second sub-mask are stacked together in the second direction.

5. The mask according to claim 4, wherein the first structure is a sawtooth protrusion with latch and the second structure is a sawtooth depression with latch concave.

6. A mask, comprising:
a first sub-mask comprising a first structure at one side edge thereof;
a second sub-mask comprising a second structure at one side edge thereof;
the first sub-mask and the second sub-mask being disposed in parallel and arranged together, and the first sub-mask and the second sub-mask are on the same plane, and the first structure and the second structure are structures complementary to each other.

7. The mask according to claim 6, wherein the first sub-mask comprises a first surface and a second surface, and the first surface and the second surface are opposite to each other, the second sub-mask comprises a third surface and a fourth surface and the third surface and the fourth surface are opposite to each other, the first sub-mask and the second sub-mask are disposed in parallel and arranged together, and the first surface of the first sub-mask and the third surface of the second sub-mask are in the same plane and the second surface of the first sub-mask and the fourth surface of the second sub-mask are on the same plane.

8. The mask according to claim 7, wherein the first structure and the second structure are structures complementary to each other in a first direction and the first direction is perpendicular to a direction of the first surface, and the first structure of the first sub-mask and the second structure of the second sub-mask are stacked together in the first direction.

9. The mask according to claim 8, wherein the first structure is a latch and the second structure is a latch groove.

10. The mask according to claim 7, wherein the first structure and the second structure are structures complementary to each other in a second direction, and the second direction is parallel to a direction of a straight line connected from a center of the first sub-mask to a center of the second sub-mask, and the first structure of the first sub-mask and the second structure of the second sub-mask are stacked together in the second direction.

11. The mask according to claim 10, wherein the first structure is a sawtooth protrusion with latch and the second structure is a sawtooth depression with latch concave.

12. A mask manufacturing method, comprising steps of:
(A) providing a first sub-mask and a second sub-mask, and one side edge of the first sub-mask comprises a first structure and one side edge of the second sub-mask comprises a second structure and the first structure and the second structure being structures complementary to each other;
(B) connecting the first sub-mask and the second sub-mask together to make the first sub-mask and the second sub-mask on the same plane and the first structure of the first sub-mask and the second structure of the second sub-mask being stacked together.

13. The mask manufacturing method according to claim 12, wherein the step (A) further comprises the steps of:
(a1) defining size and position of the first structure and the second structure to make the first structure and the second structure be structures complementary to each other;
(a2) forming the first structure on the first sub-mask and the second structure on the second sub-mask.

14. The mask manufacturing method according to claim 13, wherein the first structure of the first sub-mask and the second structure of the second sub-mask are stacked together in the first direction, the first direction is perpendicular to a direction of the first surface and the first structure is a latch and the second structure is a latch groove.

15. The mask manufacturing method according to claim 13, wherein the first structure of the first sub-mask and the second structure of the second sub-mask are stacked together in the second direction, the second direction is parallel to a direction of a straight line connected from a center of the first sub-mask to a center of the second sub-mask, and the first structure is a sawtooth protrusion with latch and the second structure is a sawtooth depression with latch concave.
